(19) United States
(12) Patent Application Publication
(10) Pub. No.: US 2025/0393272 A1
(43) Pub. Date: Dec. 25, 2025

(54) BJT WITH BACKSIDE BASE CONTACT

(71) Applicant: INTERNATIONAL BUSINESS MACHINES CORPORATION, Armonk, NY (US)

(72) Inventors: Anindya Nath, Watervliet, NY (US); Ruilong Xie, Niskayuna, NY (US); Robert Gauthier, Williston, VT (US); Anthony I-Chih Chou, Guilderland, NY (US); Masoud Zabihi, Schenectady, NY (US)

(21) Appl. No.: 18/751,700

(22) Filed: Jun. 24, 2024

(51) Int. Cl. H01L 29/10; H01L 23/498; H01L 29/417; H01L 29/423; H01L 29/735

(52) U.S. Cl. CPC H10D 62/184; H01L 23/49844; H10D 10/60; H10D 64/231; H10D 64/281

(57) ABSTRACT

Semiconductor devices include a semiconductor well layer having a first dopant polarity. A collector terminal is on a top surface of the semiconductor well layer, having a second dopant polarity. An emitter terminal is on the top surface of the semiconductor well layer, having the second dopant polarity. A conductor contacts a bottom surface of the semiconductor well layer and extends laterally below the collector terminal and the emitter terminal.

### BACKGROUND

The present invention generally relates to semiconductor device fabrication and, more particularly, to bipolar junction transistors (BJTs) with backside base contacts.

BJTs are a type of transistor that makes use of both electrons and holes to carry charges. The BJT is formed from two junctions between semiconductors of differing polarity-p-type and n-type. BJTs may be of NPN type, with a p-type region between two n-type regions, or PNP type, with an n-type region between two p-type regions.

Electrical contacts to a BJT can be formed with processing steps that come from a front side of a device or from the back side of the device, which increases the flexibility for laying out conductive interconnects. As semiconductor devices with backside interconnects become more prevalent, implementing such designs for BJTs is a challenge, as base potential control is important for BJT performance.

### SUMMARY

A semiconductor device includes a semiconductor well layer having a first dopant polarity. A collector terminal is on a top surface of the semiconductor well layer, having a second dopant polarity. An emitter terminal is on the top surface of the semiconductor well layer, having the second dopant polarity. A conductor contacts a bottom surface of the semiconductor well layer and extends laterally below the collector terminal and the emitter terminal.

A semiconductor device includes a semiconductor well layer having a first dopant polarity. A collector terminal is on a top surface of the semiconductor well layer, having a second dopant polarity. An emitter terminal is on the top surface of the semiconductor well layer, having the second dopant polarity. A base terminal has the first dopant polarity. A conductor electrically connects to the base terminal and a bottom surface of the semiconductor well layer and extends laterally below the collector terminal and the emitter terminal. A vertical dielectric barrier is between the conductor and a side surface of the semiconductor well layer and extends to a depth below a bottom surface of the semiconductor well layer.

A semiconductor device includes a semiconductor well layer having a first dopant polarity. A collector terminal is on a top surface of the semiconductor well layer, having a second dopant polarity. An emitter terminal is on the top surface of the semiconductor well layer, having the second dopant polarity. A conductor contacts a bottom surface of the semiconductor well layer and extends laterally below the collector terminal and the emitter terminal. A backside contact connects to the conductor.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a semiconductor device having a bipolar junction transistor (BJT) with a backside contact, in accordance with an embodiment of the present invention;

FIG. 2 is a cross-sectional view of a step in the fabrication of a semiconductor device having a BJT with a backside contact, showing removal of a semiconductor substrate, in accordance with an embodiment of the present invention;

FIG. 3 is a cross-sectional view of a step in the fabrication of a semiconductor device having a BJT with a backside contact, showing the partial removal of a semiconductor well layer in a region beneath a placeholder structure for a base terminal, in accordance with an embodiment of the present invention;

FIG. 4 is a cross-sectional view of a step in the fabrication of a semiconductor device having a BJT with a backside contact, showing the formation of a dielectric barrier on an exposed sidewall of the semiconductor well layer, in accordance with an embodiment of the present invention;

FIG. 5 is a cross-sectional view of a step in the fabrication of a semiconductor device having a BJT with a backside contact, showing the exposure of the placeholder structure beneath the base terminal, in accordance with an embodiment of the present invention;

FIG. 6 is a cross-sectional view of a step in the fabrication of a semiconductor device having a BJT with a backside contact, showing the formation of a backside interlayer dielectric, in accordance with an embodiment of the present invention;

FIG. 7 is a cross-sectional view of a step in the fabrication of a semiconductor device having a BJT with a backside contact, showing the formation of an opening in the backside interlayer dielectric that exposes the placeholder structure, in accordance with an embodiment of the present invention;

FIG. 8 is a cross-sectional view of a step in the fabrication of a semiconductor device having a BJT with a backside contact, showing the removal of an etch stop layer from the semiconductor well layer, in accordance with an embodiment of the present invention;

FIG. 9 is a cross-sectional view of a step in the fabrication of a semiconductor device having a BJT with a backside contact, showing the implantation of dopant on the surface of the semiconductor well layer to form a highly doped layer, in accordance with an embodiment of the present invention;

FIG. 10 is a cross-sectional view of a step in the fabrication of a semiconductor device having a BJT with a backside contact, showing the formation of a base interconnect conductor between the highly doped layer of the semiconductor well layer and the base terminal, in accordance with an embodiment of the present invention;

FIG. 11 is a cross-sectional view of a step in the fabrication of a semiconductor device having a BJT with a backside contact, showing an alternative embodiment where contact is made to the semiconductor well layer by a backside contact, in accordance with an embodiment of the present invention;

FIG. 12 is a block/flow diagram of a method of fabricating a semiconductor device having a BJT with a base interconnect between a semiconductor well layer and a base terminal, in accordance with an embodiment of the present invention; and

FIG. 13 is a block/flow diagram of a method of fabricating a semiconductor device having a BJT with a backside contact to a semiconductor well layer, in accordance with an embodiment of the present invention.

### DETAILED DESCRIPTION

Bipolar junction transistors (BJTs) may be formed with backside contacts that extend laterally to make continuous contact with the back side of a well structure. This continuous backside contact improves base potential consistency and thereby improves overall BJT performance. When lateral BJTs are used as electrostatic discharge protection device (ESD device), having an equipotential wide base enhances failure current, hence device robustness. To create the backside contact, backside processing may partially remove the substrate layer under a base terminal of the BJT. A dielectric barrier may be used to prevent these processing steps from harming the n-well underneath the emitter and collector terminals of the BJT. A backside contact may then be formed which connects the base terminal to the n-well, providing a large contact surface that extends laterally underneath both the emitter terminal and the collector terminal.

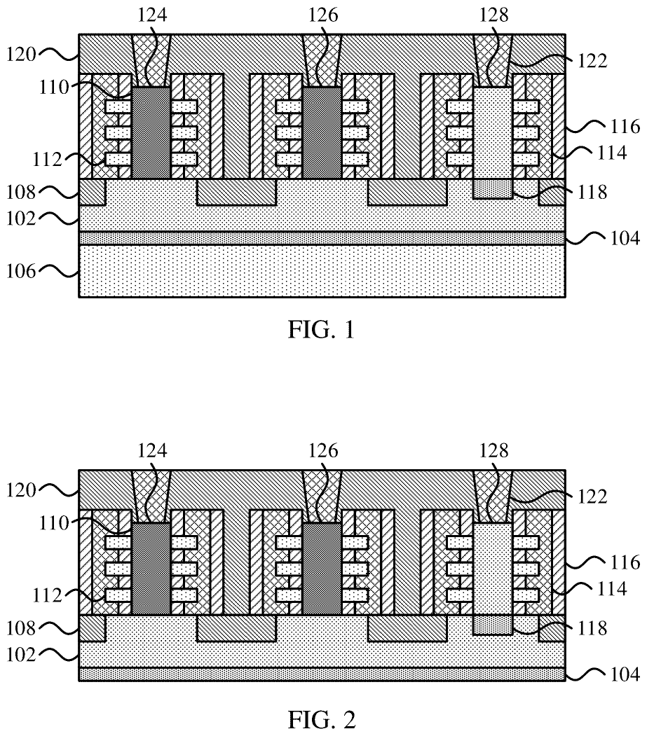

Referring now to FIG. 1, a cross-sectional view is shown of a step in the fabrication of a BJT with a backside base contact. The device is formed on a substrate that includes a semiconductor well layer 102. The semiconductor well layer 102 is formed from an appropriately doped semiconductor material, and is formed on an etch stop layer 104, with a semiconductor substrate 106 beneath it.

The semiconductor substrate 106 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

It should be understood that the present embodiments may include PNP and/or NPN BJTs, where the semiconductor well layer 102 may be doped with an n-type dopant in the case of a PNP BJT or may be doped with a p-type dopant in the case of an NPN BJT. Both types of BJT may be formed in different regions of a chip for single semiconductor device. The semiconductor well layer 102 makes up part of the base of the BJT, where current applied to the semiconductor well layer 102 controls current that flows between the collector and the emitter. Thus the semiconductor well layer 102 may be formed from doped silicon or any other appropriate semiconductor material, with a dopant that is selected in accordance with the type of BJT being formed.

The BJT includes a set of three terminals 110, including a collector terminal 124, an emitter terminal 126, and a base terminal 128. These terminals 110 may be formed from epitaxially grown doped semiconductor material and may contact a top surface of the semiconductor well layer 102. The base terminal 128 may be formed with a dopant species that has a polarity opposite to the dopant of the collector terminal 124 and the emitter terminal 126. In the case of a PNP BJT, the collector terminal 124 and the emitter terminal 126 may be formed from a semiconductor material that is doped with an appropriate p-type dopant, while the base terminal 128 may be formed with an n-type dopant. In the case of an NPN BJT, the polarities of the terminals 110 may be reversed. These dopants may be added in situ during epitaxial growth of the terminals.

The terminals 110 may be epitaxially grown from exposed side surfaces of dummy nanosheets 112. These dummy nanosheets 112 may be formed by any appropriate process, such as by epitaxial growth of alternating first and second semiconductor materials, followed by the selective removal of one of those semiconductor materials after forming dummy gates 114 and dummy gate spacers 116 to suspend the dummy nanosheets 112. Exposed portions of the dummy nanosheets 112 may be etched away to expose side surfaces, making epitaxial growth of the terminals from those side surfaces possible.

The first and second semiconductor materials may be selected to provide both crystallographic compatibility and etch selectivity with respect to one another. For example, the first semiconductor material may be silicon and may make up the dummy nanosheets 112, while the second semiconductor material may be silicon germanium having a germanium concentration between about 30% and about 60%. As used herein, the term “selective” in reference to a material removal process denotes that the rate of material removal for a first material is greater than the rate of removal for at least another material of the structure to which the material removal process is being applied.

The terms “epitaxial growth” and/or “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

Other types of material deposition that may be used herein include chemical vapor deposition (CVD), physical vapor deposition (PVD), atomic layer deposition (ALD), or gas cluster ion beam (GCIB) deposition. Some deposition processes, such as ALD, may deposit material conformally, whereas others, such as PVD or GCIB, may provide a more directional deposition. CVD may range from highly conformal to highly non-conformal depending on the formulation.

CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

The terminals 110 may be separated from one another by shallow trench isolation (STI) structures 108 in the semiconductor well layer 102. The STI structures 108 may be formed by etching trenches in the semiconductor well layer 102 and then filling the trenches with an appropriate dielectric material, such as silicon dioxide. A placeholder structure 118 may be formed underneath the base terminal 128, for example by etching another trench into the semiconductor well layer 102 and then epitaxially growing a selectively etchable semiconductor material from the trench surfaces.

A frontside interlayer dielectric 120 is deposited over the terminals 110, for example by a flowable CVD process using silicon dioxide. Vias may be etched into the frontside interlayer dielectric 120 and may be filled by conductive material to form frontside terminal contacts 122. The vias may be formed using an anisotropic etch process, such as reactive ion etching, which is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface.

Additional layers may be formed on the front side of the device, such as back-end-of-line (BEOL) layers (not shown), which include conductive interconnects and vias to provide signal and/or power connectivity to the terminals 110. At this stage, a carrier wafer (not shown) may further be bonded to the BEOL layers, so that the device may be turned upside-down for further processing, exposing the semiconductor substrate 106.

Referring now to FIG. 2, a cross-sectional view is shown of a step in the fabrication of a BJT with a backside base contact. The semiconductor substrate 106 is removed with a selective etch that stops on the etch stop layer 104. The etch may be any appropriately selective isotropic or anisotropic etch.

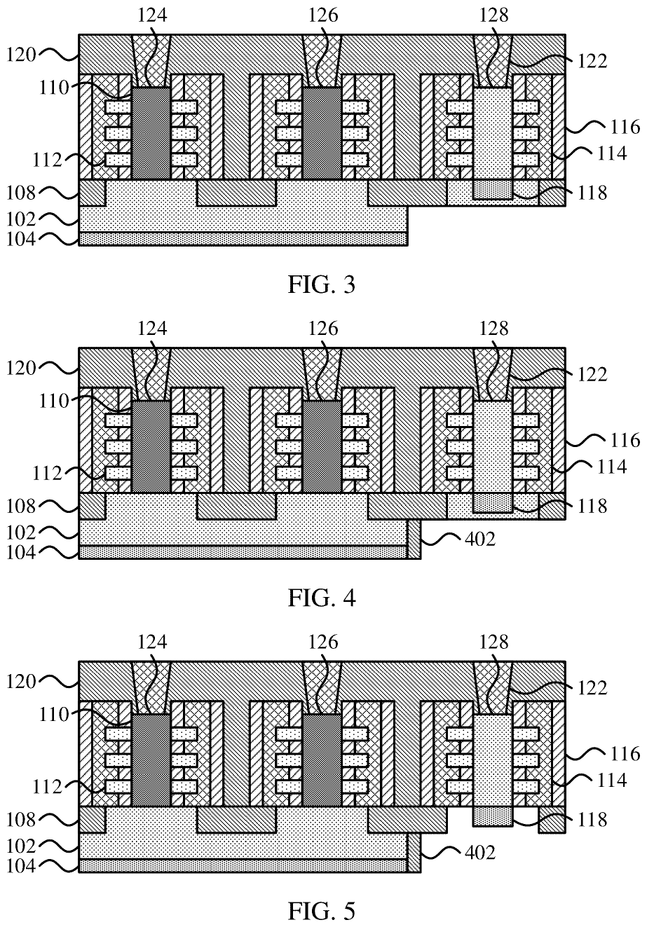

Referring now to FIG. 3, a cross-sectional view is shown of a step in the fabrication of a BJT with a backside base contact. A portion of the etch stop layer 104 and the semiconductor well layer 102 may be partially removed to expose the placeholder structure 118. This may be accomplished by forming a mask over the etch stop layer 104 from, e.g., an organic planarizing layer (OPL), and then using photolithography to create a pattern in the OPL. The OPL may then be used as a mask to selectively and anisotropically etch away the exposed material of the semiconductor well layer 102, leaving behind the portion that is covered by the OPL. The selective etch of the semiconductor well layer 102 may not be selective to overlying semiconductor materials (e.g., the silicon germanium of the placeholder structure 118) and so some of the semiconductor well layer 102 may be left in place to cover the placeholder structure 118. The OPL may then be removed, for example using an ashing process.

Referring now to FIG. 4, a cross-sectional view is shown of a step in the fabrication of a BJT with a backside base contact. A vertical dielectric barrier 402 is formed on an exposed sidewall of the remaining semiconductor well layer 102. The dielectric barrier may be formed by conformally depositing a dielectric material, such as silicon dioxide, and then selectively and anisotropically etching the dielectric material to remove it from horizontal surfaces. The vertical dielectric barrier 402 also extends along the side surface of the etch stop layer 104, so that it extends beyond the bottom surface of the semiconductor well layer 102.

Referring now to FIG. 5, a cross-sectional view is shown of a step in the fabrication of a BJT with a backside base contact. Any exposed material from the semiconductor well layer 102 is etched away, with the remaining material of the semiconductor well layer 102 being protected by the etch stop layer 104 and the vertical dielectric barrier 402. Due to etch selectivity, the placeholder structure 118 is preserved.

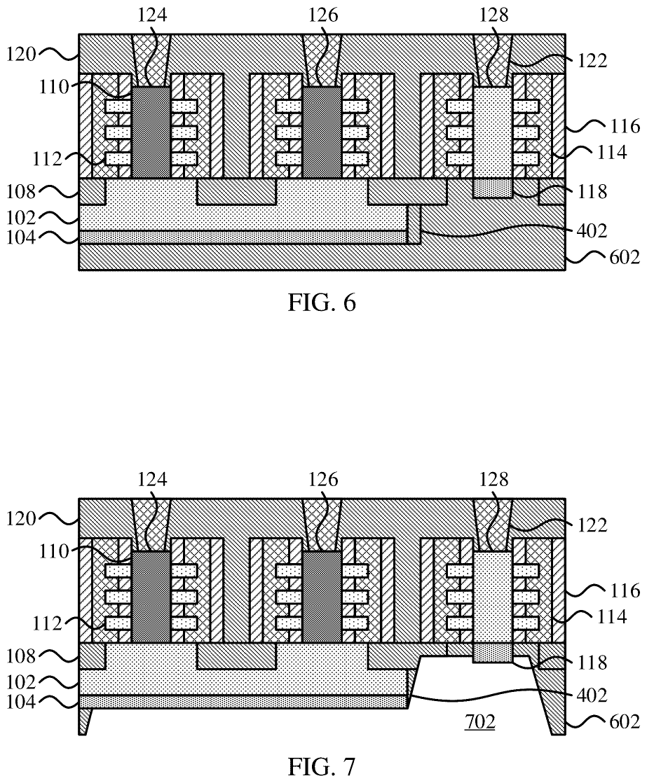

Referring now to FIG. 6, a cross-sectional view is shown of a step in the fabrication of a BJT with a backside base contact. A backside interlayer dielectric 602 is deposited by any appropriate deposition process, for example using a flowable CVD to cover the back side of the device with silicon dioxide.

Referring now to FIG. 7, a cross-sectional view is shown of a step in the fabrication of a BJT with a backside base contact. The backside interlayer dielectric 602 is patterned and selectively etched to create opening 702. The opening exposes the etch stop layer 104 as well as the placeholder structure 118, incidentally etching into exposed portions of the vertical dielectric barrier 402 and the STI structures 108, which may be formed from the same material as the backside interlayer dielectric 602.

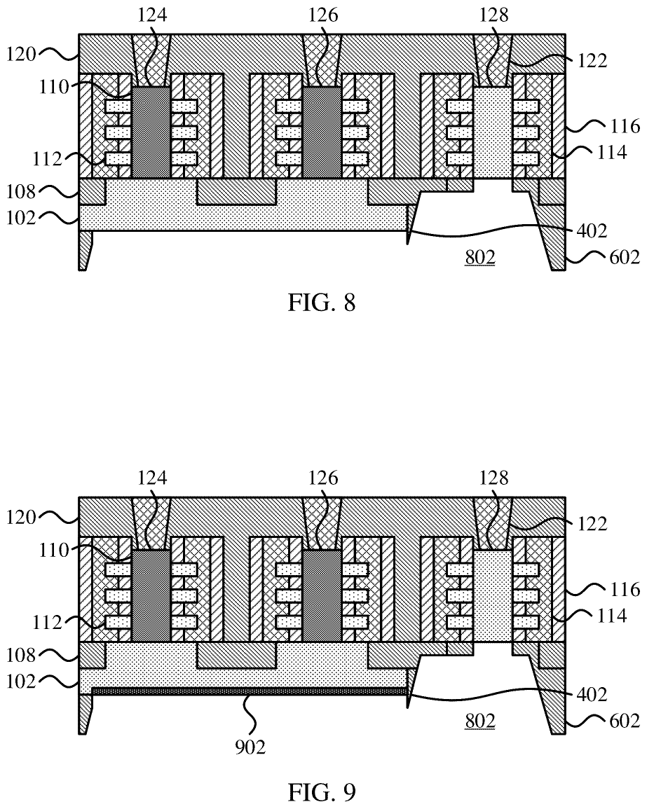

Referring now to FIG. 8, a cross-sectional view is shown of a step in the fabrication of a BJT with a backside base contact. The etch stop layer 104 and the placeholder structure 118, which may be formed from the same material, are selectively etched away to expose the back side surfaces of the semiconductor well layer 102 and the base terminal 128. Removal of these structures expands the opening 802.

Referring now to FIG. 9, a cross-sectional view is shown of a step in the fabrication of a BJT with a backside base contact. Additional dopant may be implanted in the back side of the semiconductor well layer 102, the dopant having the same polarity as the semiconductor well layer 102. For example in a PNP BJT, where the semiconductor well layer 102 includes an n-type dopant, the additional dopant may be an n-type dopant. An anneal may be performed, for example a laser anneal, for dopant activation, defect annealing, and to cause the additional dopant to diffuse into the semiconductor well layer 102. The result is a layer 902 of more highly doped material at the surface of the semiconductor well layer 102, where the highly doped layer 902 has a higher concentration of dopant relative to the remainder of the semiconductor well layer 102. The highly doped layer 902 may be about 40-50 nm thick and provides a low-resistance contact to the semiconductor well layer 102.

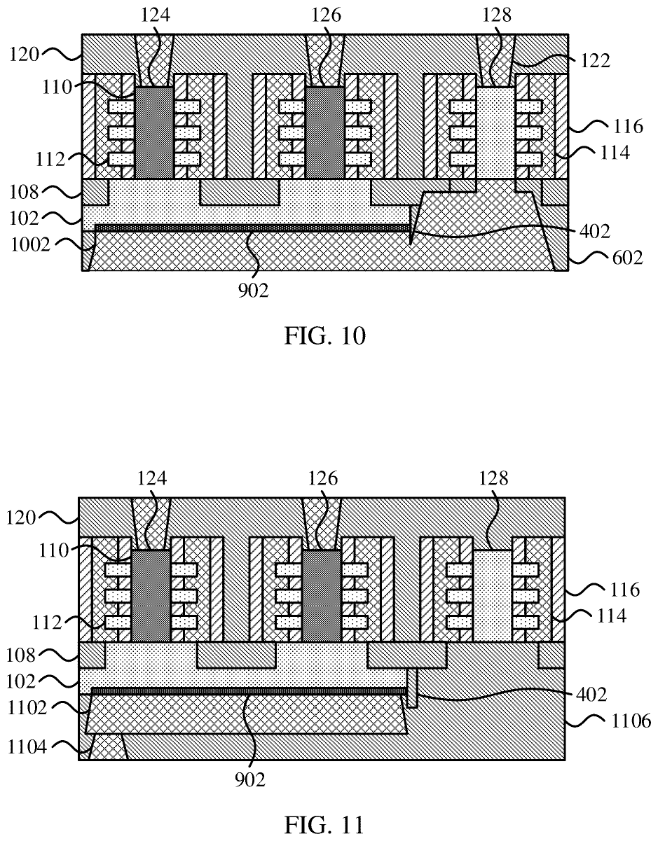

Referring now to FIG. 10, a cross-sectional view is shown of a step in the fabrication of a BJT with a backside base contact. The opening 802 is filled with conductive material by any appropriate deposition process. Excess conductive material may be removed using a chemical mechanical planarization (CMP) process. CMP is performed using, e.g., a chemical or granular slurry and mechanical force to gradually remove upper layers of the device. The slurry may be formulated to be unable to dissolve, for example, the backside interlayer dielectric 602, resulting in the CMP process's inability to proceed any farther than that layer. The conductive material that remains in the opening 802 forms base interconnect conductor 1002 on the bottom surface of the semiconductor well layer 102.

In some embodiments, the base interconnect forms an electrical connection between the base terminal 128 and the semiconductor well layer 102, with a top surface of the base interconnect being parallel with a top surface of the semiconductor well layer 102. Taken together, these structures can act as the base of the BJT. During operation, current may be applied to the base terminal 128 to operate the BJT.

Referring now to FIG. 11, a cross-sectional view is shown of a step in the fabrication of an alternative embodiment of a BJT with a backside base contact. In some embodiments, the BJT may be operated by applying a base current from the back side of the device rather than from the front side of the device. In such embodiments, the base terminal 128 may be omitted, or may simply be left floating when forming conductive contacts. Instead, a base contact conductor 1102 may be formed, again along the back side of the semiconductor well layer 102, but with a backside contact 1104 that provides electrical access from the back side of the device. The backside contact 1104 may be embedded in a backside interlayer dielectric 1106.

Additional layers may be formed on the back side of the device, such as backside power distribution network layers (not shown), which include conductive interconnects and vias to provide signal and/or power connectivity to the backside contact 1104. The backside power distribution layers may be formed on the backside interlayer dielectric 1106 in one or more iterations, depositing a dielectric layer, etching the dielectric layer to form trenches and vias, and depositing conductive material.

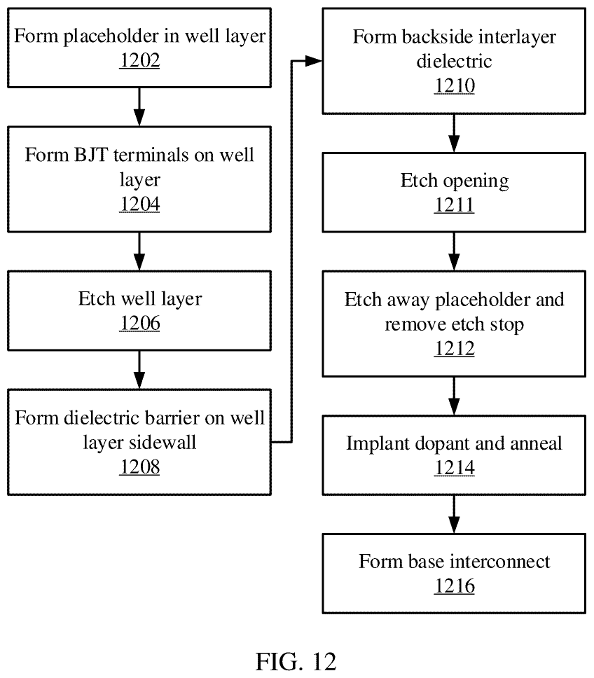

Referring now to FIG. 12, a method of forming a semiconductor device with frontside contacts to a base of a BJT is shown. Before the terminals 110 are formed on a semiconductor well layer 102, block 1202 forms a placeholder structure 118 in the semiconductor well layer. Block 1204 then forms the terminals 110, for example by epitaxially growing them from the dummy nanosheets 112. This may be performed in two distinct epitaxial growth processes, for example with in situ doping using a first dopant on the collector terminal 124 and the emitter terminal 126 and using a second dopant in a separate growth process for the base terminal 128. Frontside terminal contacts 122 may be formed after the formation of the terminals 110, through a frontside interlayer dielectric 120.

Block 1206 partially etches the semiconductor well layer 102, removing the semiconductor substrate 106 and then masking the etch stop layer 104 using, e.g., an OPL. An anisotropic etch may remove some or all of the exposed material of the semiconductor well layer 102 in the region below the base terminal 128. Block 1208 then forms a vertical dielectric barrier 402 on an exposed sidewall of the semiconductor well layer 102 by conformally depositing dielectric material and anisotropically removing the dielectric material from horizontal surfaces.

Block 1210 forms backside interlayer dielectric 602 using any appropriate deposition process. Block 1211 etches an opening 702 into the backside interlayer dielectric 602 using a photolithographic process, exposing the etch stop layer 104 and the placeholder structure 118. Block 1212 etches away the exposed portions of the etch stop layer 104 and the placeholder structure 118 to expose the back surfaces of the semiconductor well layer 102 and the base terminal 128.

Block 1214 implants additional dopant in the semiconductor well layer 102 and performs a laser anneal to create highly doped layer 902. Block 1216 forms the base interconnect conductor 1002 by depositing conductive material and polishing back to the backside interlayer dielectric 602 using a CMP process. The base interconnect conductor 1002 electrically connects the semiconductor well layer 102 to the base terminal 128.

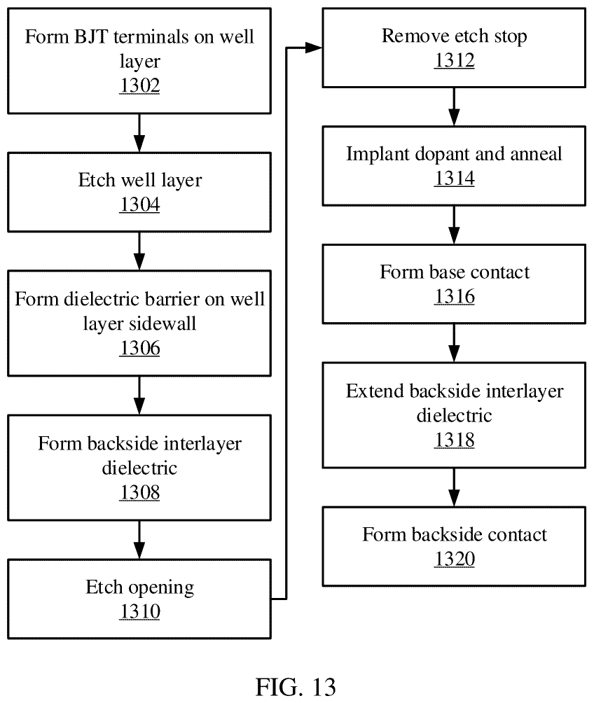

Referring now to FIG. 13, a method of forming a semiconductor device with a backside base contact for a BJT is shown. Block 1302 forms BJT terminals 110 on a semiconductor well layer 102. In contrast to the embodiment of FIG. 12, no placeholder structure 118 is used and the base terminal 128 may be omitted entirely. Block 1304 partially etches the semiconductor well layer 102 to a region below the collector terminal 124 and the emitter terminal 126. Block 1306 forms vertical dielectric barrier 402 on the exposed sidewall of the semiconductor well layer 102 by conformally depositing dielectric material and anisotropically etching away the dielectric material from horizontal surfaces.

Block 1308 forms a backside interlayer dielectric 602 to cover the semiconductor well layer 102 and block 1310 etches an opening into the backside interlayer dielectric 602. The opening exposes the etch stop layer 104. Block 1312 removes the etch stop layer 104 using an appropriately selective etch. Block 1314 implants additional dopant in the semiconductor well layer 102 and performs a laser anneal to create highly doped layer 902. Block 1316 forms the base contact conductor 1102 by depositing conductive material and polishing back to the backside interlayer dielectric 602 using a CMP process. Block 1318 extends the backside interlayer dielectric 1106 by depositing additional dielectric material over the base contact conductor 1102. Block 1320 forms backside contact 1104 by etching a via through the backside interlayer dielectric 1106 and depositing conductive material, with excess conductive material being removed by, e.g., a CMP process.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below”, or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a BJT with backside base contact (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a semiconductor well layer having a first dopant polarity;
a collector terminal on a top surface of the semiconductor well layer, having a second dopant polarity;
an emitter terminal on the top surface of the semiconductor well layer, having the second dopant polarity; and
a conductor that contacts a bottom surface of the semiconductor well layer and that extends laterally below the collector terminal and the emitter terminal.

2. The semiconductor device of claim 1, further comprising a base terminal having the first dopant polarity, wherein the conductor electrically connects the base terminal and the semiconductor well layer.

3. The semiconductor device of claim 2, wherein the conductor has a top surface that is parallel to the top surface of the semiconductor well layer and wherein the base terminal is positioned on the top surface of the conductor.

4. The semiconductor device of claim 2, further comprising a vertical dielectric barrier between the conductor and a side surface of the semiconductor well layer, the vertical dielectric barrier extending to a depth below a bottom surface of the semiconductor well layer.

5. The semiconductor device of claim 2, further comprising respective frontside contacts to the collector terminal, the emitter terminal, and the base terminal.

6. The semiconductor device of claim 1, wherein the semiconductor well layer includes a highly doped layer at the bottom surface that has a higher dopant concentration than a remainder of the semiconductor well layer.

7. The semiconductor device of claim 6, wherein the highly doped layer has a thickness between about 40 nm and about 50 nm from the bottom surface of the semiconductor well layer.

8. The semiconductor device of claim 1, further comprising a backside contact to the conductor.

9. The semiconductor device of claim 8, further comprising a terminal adjacent to the collector terminal and the emitter terminal, having the first dopant polarity, that is not electrically connected to the semiconductor well layer.

10. The semiconductor device of claim 8, further comprising respective frontside contacts to the collector terminal and to the emitter terminal.

11. A semiconductor device, comprising:
a semiconductor well layer having a first dopant polarity;
a collector terminal on a top surface of the semiconductor well layer, having a second dopant polarity;
an emitter terminal on the top surface of the semiconductor well layer, having the second dopant polarity;
a base terminal having the first dopant polarity;
a conductor that electrically connects to the base terminal and a bottom surface of the semiconductor well layer and that extends laterally below the collector terminal and the emitter terminal; and
a vertical dielectric barrier between the conductor and a side surface of the semiconductor well layer, the vertical dielectric barrier extending to a depth below a bottom surface of the semiconductor well layer.

12. The semiconductor device of claim 11, wherein the base terminal is on a surface of the conductor that is parallel to the top surface of the semiconductor well layer.

13. The semiconductor device of claim 11, further comprising respective frontside contacts to the collector terminal, the emitter terminal, and the base terminal.

14. The semiconductor device of claim 11, wherein the semiconductor well layer includes a highly doped layer at the bottom surface that has a higher dopant concentration than a remainder of the semiconductor well layer.

15. The semiconductor device of claim 14, wherein the highly doped layer has a thickness between about 40 nm and about 50 nm from the bottom surface of the semiconductor well layer.

16. A semiconductor device, comprising:
a semiconductor well layer having a first dopant polarity;
a collector terminal on a top surface of the semiconductor well layer, having a second dopant polarity;
an emitter terminal on the top surface of the semiconductor well layer, having the second dopant polarity;
a conductor that contacts a bottom surface of the semiconductor well layer and that extends laterally below the collector terminal and the emitter terminal; and
a backside contact to the conductor.

17. The semiconductor device of claim 16, wherein the semiconductor well layer includes a highly doped layer at the bottom surface that has a higher dopant concentration than a remainder of the semiconductor well layer.

18. The semiconductor device of claim 17, wherein the highly doped layer has a thickness between about 40 nm and about 50 nm from the bottom surface of the semiconductor well layer.

19. The semiconductor device of claim 16, further comprising a terminal having the first dopant polarity that is not electrically connected to the semiconductor well layer.

20. The semiconductor device of claim 16, further comprising respective frontside contacts to the collector terminal and to the emitter terminal.
